(19) United States
(12) Patent Application Publication
(10) Pub. No.: US 2026/0206477 A1
(43) Pub. Date: Jul. 16, 2026

(54) AZEOTROPE-PROCESSED SELF-ASSEMBLED MONOLAYER AND SOLAR CELL FORMED WITH THE SAME

(71) Applicant: CITY UNIVERSITY OF HONG KONG, Kowloon (HK)

(72) Inventors: Hin Lap YIP, Kowloon (HK); Gengxin DU, Kowloon (HK)

(21) Appl. No.: 19/346,737

(22) Filed: Oct. 1, 2025

Related U.S. Application Data
(60) Provisional application No. 63/745,557, filed on Jan. 15, 2025.

(51) Int. Cl. H10K 71/15; C07F 9/572; H10K 30/40

(52) U.S. Cl. CPC H10K 71/15; C07F 9/5728; H10K 30/40

(57) ABSTRACT

A solution of self-assembled monolayer (SAM) molecules is disclosed as SAM molecules dissolved in an azeotropic solvent system including toluene and isopropanol. A method of forming a SAM film on a substrate is also disclosed as including applying the above solution of on an ITO substrate by slot-die coating. A solar cell is disclosed as including the above substrate with a SAM film.

### FIELD OF THE INVENTION

This invention generally relates to azeotrope-processed self-assembled monolayer and solar cells (including organic solar cells (OSCs) and perovskite solar cells (PSCs) formed with such self-assembled monolayers.

### BACKGROUND OF THE INVENTION

Organic solar cells (OSCs) and perovskite solar cells (PSCs) have garnered significant attention due to their lightweight properties, tunable optical transparency, solution processibility, and potential for more sustainable production. Advances in material design, device physics, and interfacial engineering have propelled the power conversion efficiency (PCE) of single-junction OSCs beyond 20% and over 26% for PSCs for small-area devices (≤0.1 cm²). However, the scalability of OSCs and PSCs remains a challenge due to the intrinsic limitations such as carrier-transporting kinetics in the organics and increased inhomogeneity and defect density in thin films during large-area production. These factors significantly impede the efficiency of large-area OSCs and PSCs, thus hindering their commercialization. Efforts to develop large-area processing techniques (≥1 cm²) that minimize scale-up loss and are compatible with future roll-to-roll production are therefore intensifying.

In conventional OSCs and PSCs with a p-i-n configuration, the hole-selective layer (HSL) plays a crucial role in modifying the work function of anode, facilitating hole extraction, and templating the morphology of the active layer processed atop. However, the commonly used HSL poly(3,4-ethylenedioxythiophene) polystyrene sulfonate (PEDOT:PSS) and PTAA in PSCs present several drawbacks including non-ideal energy levels, acidic, hygroscopic, and significant parasitic absorption, all of which compromise device stability and efficiency. Moreover, phase segregation in the PEDOT:PSS composite can create pinholes during device processing and operation, leading to electrical shorting, which is a particularly critical issue in large-area devices. To address these challenges, researchers have explored the use of self-assembly monolayers (SAMs) as a replacement for PEDOT:PSS and PTAA. SAMs form robust chemical bonds on ITO substrates, offering tunable energy levels, higher optical transmittance, and enhanced device stability. Nevertheless, there are still multiple challenges associated with SAM processing. Particularly, processing SAM molecules, which are generally amphiphilic and form micelles in the precursor ink, remains challenging, especially on rough ITO surfaces. Although there have been reports of OSC and PSC modules employing SAM as an HSL, achieving a low defect density on ITO typically shows poor reproducibility and requires dynamic processing techniques like spin-coating, which do not translate well to large substrates. These limitations render the fabrication of large-area OSCs with a high-quality SAM HSL extremely challenging.

Recent developments in co-SAM and co-solvent strategies have improved SAM quality for perovskite solar cells. The co-SAM strategy introduces an additive SAM to fill the vacancy in the host SAM to enable denser monolayer formation. On the other hand, the co-solvent strategy introduces a small amount of highly solvating N,N-dimethylformamide (DMF) into isopropanol (IPA), which helps to disassemble the SAM micelles into dispersed molecules, offering an optimized and more controllable SAM deposition process. However, the differences in surface tension and saturated vapor pressure (as shown in Tables 1 and 2 below) of the co-solvents introduce instability, particularly problematic in large-area printing due to prolonged process times as solvent composition deviates over time due to the different evaporate rate of the solvents. This instability exacerbates issues like Marangoni flow and hinders the formation of a uniform film. In addition, the residual high boiling point additives are hard to remove and could affect the morphology of the OSC active layer processed atop.

TABLE 1
Surface tension of different solvents @ 20° C.

| | Surface tension (mN/m) |
|---|---|
| Toluene | 28.54 |
| IPA | 21.32 |
| DMF | 37.15 |

TABLE 2
Standard vapor pressure of different solvents @ 20° C.

| | Saturated vapor pressure (kPa) |
|---|---|
| Toluene | 2.911 |
| IPA | 4.418 |
| DMF | 0.360 |

It is therefore an objective of the present invention to provide a solution of self-assembled monolayer (SAM) molecules, a method of forming a SAM film on a substrate and an organic solar cell in which the aforesaid shortcomings are mitigated or at least to provide a useful alternative to the trade and public.

### SUMMARY OF THE INVENTION

According to a first aspect of the present invention, there is provided a solution of self-assembled monolayer (SAM) molecules, including a plurality of SAM molecules dissolved in at least two solvents which form an azeotropic solvent system.

According to a second aspect of the present invention, there is provided a method of forming a SAM film on a substrate, including applying a solution of SAM molecules on a substrate by coating, wherein said solution includes a plurality of SAM molecules dissolved in at least two solvents which form an azeotropic solvent system.

According to a third aspect of the present invention, there is provided an organic solar cell including a substrate with a SAM film, wherein said SAM film is formed on said substrate by applying a solution of SAM molecules on said substrate by coating, and wherein said solution includes a plurality of SAM molecules dissolved in at least two solvents which form an azeotropic solvent system.

According to a fourth aspect of the present invention, there is provided use of an azeotropic solvent mixture including at least two solvents in solution-processing film fabrication to maintain consistent solvent composition during film fabrication

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Embodiments of the present invention will now be described, by way of examples only, with reference to the accompanying drawings, in which:

FIG. 1A shows the typical structure of a SAM molecule;

FIG. 1B shows the molecular structures of (4-(3,6-diphenyl-9H-carbazol-9-yl)butyl)phosphonic acid (hereinafter referred to as “Cbz-2Ph”), IPA, and toluene, along with schematic illustrations showing the behavior of Cbz-2Ph molecules in these solvents, highlighting the formation of micelles in IPA, and a reversed micelle structure which may be formed in toluene;

FIG. 2 shows dynamic light scattering (DLS) result of Cbz-2Ph in IPA, IPA:toluene azeotrope, and toluene (fresh);

FIG. 3 shows the calculated size of Cbz-2Ph molecule in vacuum (X-direction: 1.732 nm, Y-direction: 1.671 nm, Z-direction: 0.661 nm);

FIG. 4 shows (a) turbid suspension of Cbz-2Ph in toluene, and (b) clear solution in IPA:toluene azeotrope;

FIG. 5 shows scattering under a laser beam of Cbz-2Ph SAM in (a) toluene and (b) IPA:toluene azeotrope;

FIG. 6 shows DLS result of Cbz-2Ph in IPA, IPA:toluene azeotrope, and toluene after 45 days of storage;

FIG. 7 shows Cbz-2Ph in IPA:toluene azeotrope (left) and IPA (right) after 45 days of storage, in which apparent crystallization can be observed as shown in the rectangle;

FIG. 8 shows an optical image of slot-die coating platform, in which the effective width of the coating head is 10 mm;

FIG. 9 shows contact angle measurements of water on azeotrope-processed Cbz-2Ph SAM (azeotrope-SAM);

FIG. 10 shows contact angle measurements of water on IPA-processed Cbz-2Ph SAM (IPA-SAM);

FIG. 11 shows transmission spectra of ITO/IPA-SAM and ITO/azeotrope-SAM, and the reference line is bare ITO;

FIG. 12 shows a schematic illustration of observation in reflection mode to expose the pinholes in PM6:BTP-eC9 layer;

FIGS. 13a and 13b show optical images (187 μm×140 μm) of, respectively, azeotrope-SAM/PM6:BTP-eC9/Ag and IPA-SAM/PM6:BTP-eC9/Ag structure respectively.

FIGS. 13c and 13d show binarization images (187 μm×140 μm) of, respectively, azeotrope-SAM/PM6:BTP-eC9/Ag and IPA-SAM/PM6:BTP-eC9/Ag structure;

FIG. 13e shows statistical counts of defects from 9 binarization images (187 μm×140 μm) of IPA-SAM group and azeotrope-SAM groups respectively;

FIGS. 14 and 15 show optical images of PM6:BTP-eC9/Ag films deposited on azeotrope-SAM and IPA-SAM, respectively (observed from the Cbz-2Ph side). The scale bar is 50 μm;

FIG. 16 shows atomic force microscope (AFM) height images of azeotrope-SAM and IPA-SAM;

FIG. 17 shows AFM height image of bare ITO (Root mean square (RMS) roughness=2.69 nm);

FIG. 18 shows surface potential distribution images from Kelvin probe force microscope (KPFM) of azeotrope-SAM and IPA-SAM;

FIG. 19 shows potential distribution of azeotrope-SAM and IPA-SAM;

FIG. 20 shows (a) KPFM potential image and (b) potential distribution of bare ITO;

FIG. 21 shows ultraviolet photoelectron spectroscopy (UPS) results of bare ITO, ITO/azeotrope-SAM, and IPA-SAM;

FIG. 22 shows an energy-level diagram of ITO, IPA-SAM modified ITO, and azeotrope-SAM modified ITO (W_{F}, E_{F}, and E_{Δ} represent work function, Fermi energy level, and energy gap between E_{F} and HOMO of Cbz-2Ph SAM);

FIG. 23 shows UPS spectra (using He I lamp with a photon energy of 21.22 eV) of (a) ITO/azeotrope-SAM and (b) ITO/IPA-SAM;

FIGS. 24a-c show cyclic voltammograms of a) bare ITO, b) ITO/azeotrope-SAM, c) ITO/IPA-SAM in orthodichlorobenzene (o-DCB) solution under different scan rates.

FIGS. 24d-e show corresponding peak current vs. scan rate chart of ITO/azeotrope-SAM and ITO/IPA-SAM, respectively;

FIG. 25 shows XPS spectra of (a) ITO/azeotrope-SAM and (b) ITO/IPA-SAM

FIG. 26 shows power conversion efficiency (PCE) distribution of 20 independent devices fabricated in one batch based on azeotrope-SAM and IPA-SAM;

FIG. 27 shows parameter distribution of the 20 devices in one batch (a) open-circuit voltage (VOC), (b) short-circuit current density (JSC), (c) fill factor (FF);

FIG. 28 shows J-V curves of the devices in FIG. 26;

FIG. 29 shows absorption of PM6:BTP-ec9 layer with a thickness of about 100 nm on IPA-SAM and azeotrope-SAM, respectively;

FIG. 30 shows external quantum efficiency (EQE) and integrated current lines of the devices in FIG. 26;

FIG. 31 shows (a) transient photocurrent and (b) photovoltage of OSCs with IPA-SAM and azeotrope-SAM, respectively;

FIG. 32 shows dark current of the devices in FIG. 26;

FIG. 33 shows PCE statistics for the top 20 independent devices (out of 80 devices) adopting azeotrope-SAM and IPA-SAM;

FIG. 34 shows J-V curves of the organic solar cells adopting D18:BTP-eC9 as the active layer on IPA-SAM and azeotrope-SAM, respectively;

FIG. 35 shows AFM height images of (a) BHJ (PM6:BTP-eC9) on ITO/azeotrope-SAM by spin coating, (b) ESL (PNDIT-F3N) on ITO/azeotrope-SAM/BHJ by spin coating, (c) BHJ (PM6:BTP-eC9) on ITO/azeotrope-SAM by slot-die coating, and (d) ESL (PNDIT-F3N) on ITO/azeotrope-SAM/BHJ by slot-die coating;

FIG. 36 shows PCE evolution of printed OSCs by slot-die coating (area 50.1 cm²);

FIG. 37 shows J-V curves of 1.0-cm² device (with a structure of ITO/azeotrope-SAM/PM6:BTP-eC9 (slot-die coated)/PNDIT-F3N (slot-die coated)/Ag) and 0.04-cm² device (with a structure of ITO/azeotrope-SAM/PM6:BTP-eC9:L8BO-2F (spin-coated)/PNDIT-F3N (spin coated)/Ag);

FIG. 38 shows J-V curves of 1-cm² devices;

FIG. 39 shows PCE record (over 10%) for 1-cm² devices by large-area processing techniques (“other methods” indicates other large-area processing techniques except for blade coating and slot-die coating, and “multi-layer” means that at least two layers among the HSL, active layer, and ESL were fabricated by scalable processing technologies, the related literature being summarized in Table 11;

FIG. 40 shows MPP tracking for small-area devices (0.04 cm²) based on azeotrope-SAM and PEDOT:PSS HSLs;

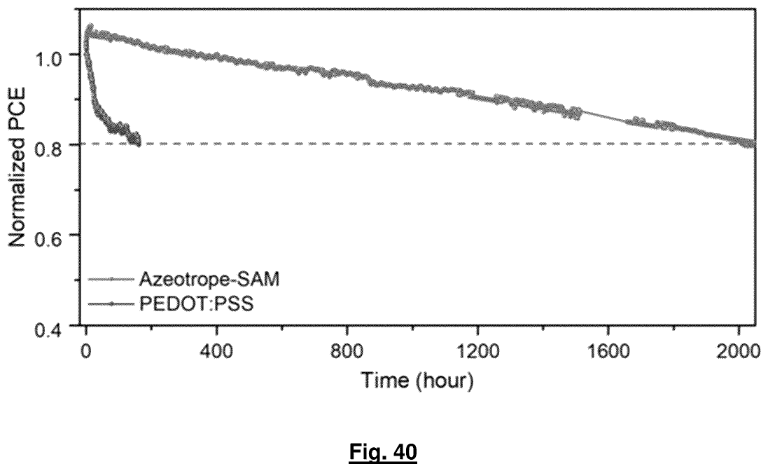

FIG. 41 shows peel-off tests of PM6 film on ITO substrates coated with azeotrope-SAM and PEDOT:PSS;

FIG. 42 shows schematic illustration of (a) peel-off test and (b) a scene of the peel-off test;

FIG. 43 shows (a) temperature variation of thermal cycling test, (b) PCE evolution of PEDOT:PSS and SAM devices after thermal cycling, and (c) PCE evolution of PEDOT:PSS and SAM based flexible devices (PET/ITO/SAM or PEDOT:PSS/PM6:BTP-eC9/PNDIT-F3N/Ag) in bending tests (with a bending radius of 6 mm);

FIG. 44 shows the molecular formula of Cbz-NaPh SAM; and

FIG. 45 shows J-V curve of PSCs based on IPA-treated Cbz-NaPh and azeotrope-treated Cbz-NaPh, with detailed parameters shown in the graph.

### DETAILED DESCRIPTION OF THE EMBODIMENTS

This present invention provides an azeotrope strategy to mitigate the issues arising from the complex evaporation kinetics of mixed solvents in the deposition of high-quality SAM on indium tin oxide (ITO) or fluorine-doped tin oxide (FTO) substrates through, coating, such as slot-die coating. This invention is applicable to a variety of solutes that dissolve/disperse poorly in solvents, especially SAM molecules, such as phosphonic acid SAMS (—PO₃H₂).

Azeotrope holds an equilibrium of fixed solvent composition at the azeotrope point, and can thus maintain consistent solvent composition during film fabrication. An azeotrope composed of toluene (42 wt %) and IPA (58 wt %) was adopted, achieving better dispersion of Cbz-2Ph SAM molecules and enhanced shelf stability of the SAM ink. The azeotrope-processed SAM shows improved coverage on ITO substrates and optimized energetic alignment with the donor material, such as Poly[[4,8-bis[5-(2-ethylhexyl)-4-fluoro-2-thienyl]benzo-[1,2-b:4,5-b′]dithiophene-2,6-diyl]-2,5-thiophenediyl-[5,7-bis(2-ethylhexyl)-4,8-dioxo-4H,8H-benzo[1,2-c:4,5-c′]-ithiophene-1,3-diyl]-2,5-thiophenediyl](PM6). Building on the high-quality azeotrope-SAM of Cbz-2Ph, a PM6:BTP-eC9 (“BTP-eC9” being 2,2′-[[12,13-Bis(2-butyloctyl)-12,13-dihydro-3,9-dinonylbisthieno[2″,3″:4′,5′]thieno[2′,3′:4,5]pyrrolo[3,2-e:2′,3′-g][2,1,3]benzothiadiazole-2,10-diyl]bis[methylidyne(5,6-chloro-3-oxo-1H-indene-2,1(3H)-diylidene)]]bis[propanedinitrile]) bulk-heterojunction (BHJ) layer and a PNDIT-F3N electron-selective layer (ESL) were printed, achieving a power conversion efficiency (PCE) of 18.89%, which is superior to devices based on IPA-processed SAM and spin-coated PEDOT:PSS. Additionally, the azeotrope-SAM devices exhibit improved operational stability, achieving a T₈₀ lifetime of over 2,000 hours. Even more promisingly, A PCE of 17.76% was attained on large-area devices (1.008 cm²) with a fully printed p-i-n stack, marking the highest efficiency reported for an all-functional-layer-printed 1-cm² device, excluding top/bottom electrodes. This invention not only exemplifies the potential of printed OSCs and PSCs based on SAM HSL but also suggests that the azeotrope strategy could revolutionize large-scale OSC and PSC manufacturing.

### Results and Discussion

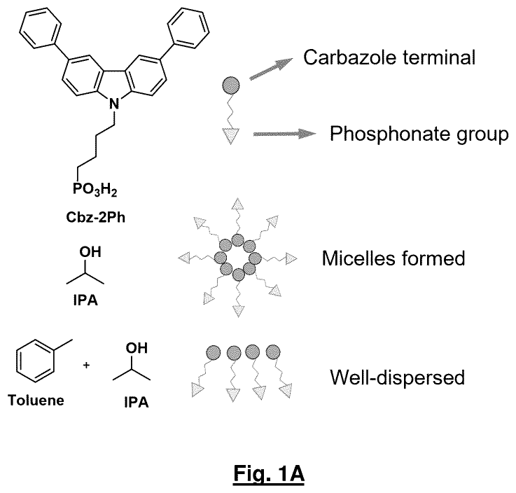

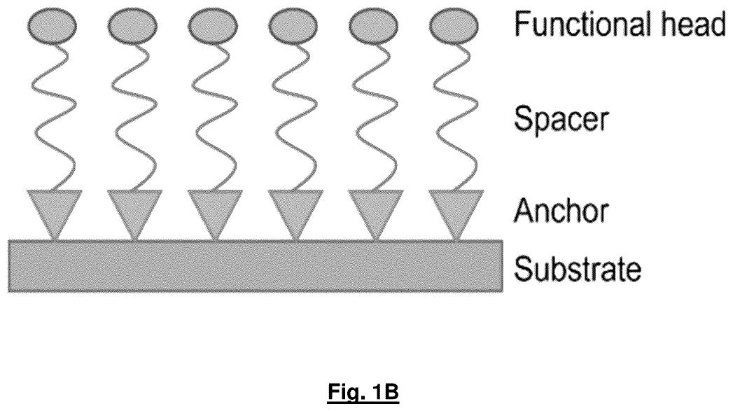

As shown in FIG. 1A, SAM molecules feature a structure with an anchoring group, a spacer group and a functional head group. The anchoring group determines the bonding strength between the substrate and the SAMS. The spacer group connects the functional head and the anchoring group. The functional head group is to achieve the target functionalities on the applied surfaces.

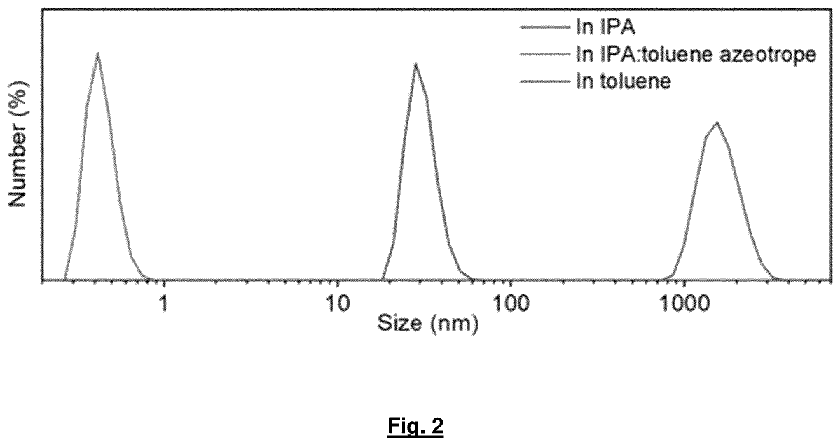

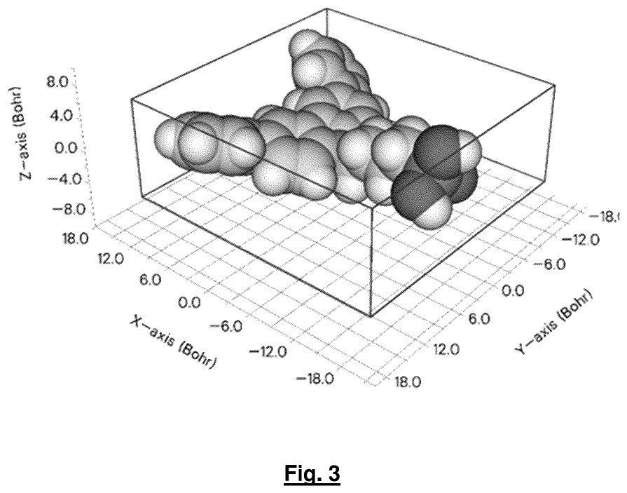

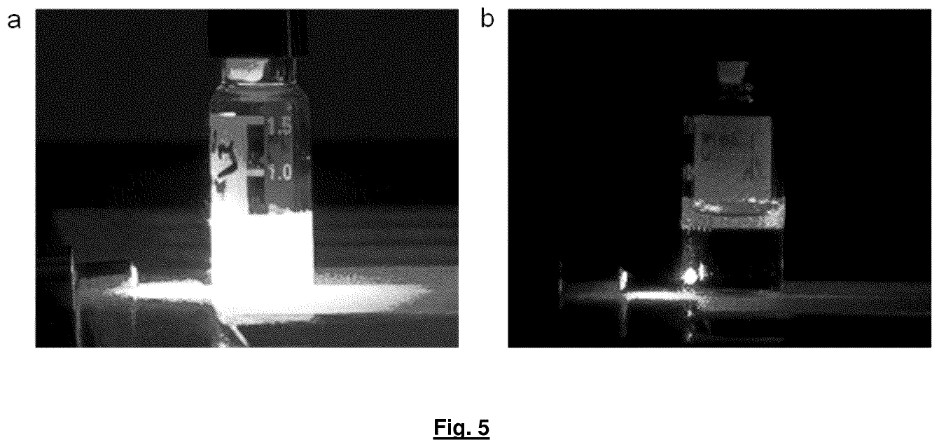

At present, SAMs used in OSCs typically consist of a phosphonic acid anchoring group and a functional carbazole head group, exhibiting intrinsic amphiphilicity. The phosphonic acid group is highly polar and hydrophilic (see FIG. 1B), allowing for strong interactions with commonly used polar solvents like isopropanol (IPA) for SAM processing. Conversely, the carbazole head, which can be further functionalized with other conjugated moieties or halide groups, is hydrophobic and interacts more favorably with aromatic solvents such as toluene. Attempts were made to dissolve Cbz-2Ph in IPA at a concentration of 1 mg/mL. Dynamic light scattering (DLS) study revealed that under such conditions, the Cbz-2Ph forms particles with an average size of ~30 nm (see FIG. 2), which is significantly larger than the size of a single molecule as simulated by the Multiwfn program (see FIG. 3) and indicates the formation of micelles. However, dissolving Cbz-2Ph in toluene resulted in a turbid suspension with DLS study detecting particle size over 1000 nm (see FIGS. 2, 4 and 5), indicating severe aggregation of the molecules in nonpolar solvent. Subsequently, adding IPA dropwise into the turbid toluene suspension gradually turns it into clear solution, indicating the breakdown of the aggregates. The solute in the resulting solution was identified with the size of single molecules from the DLS study, indicating that Cbz-2Ph is well dispersed in the mixed IPA:toluene solvent, as shown in FIG. 1.

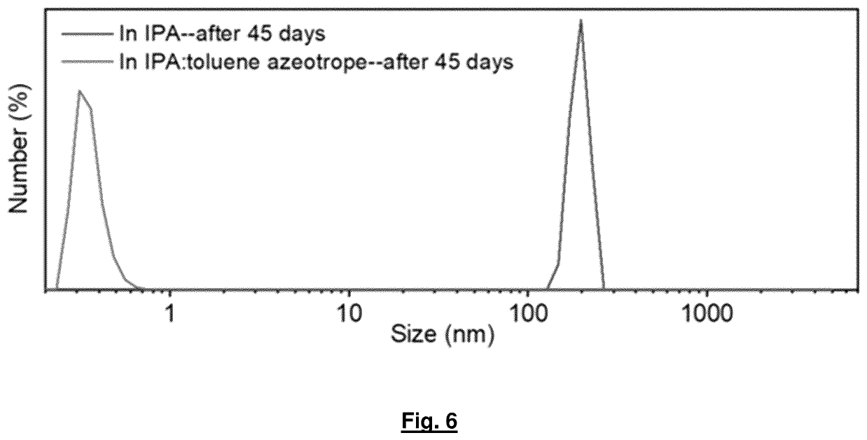

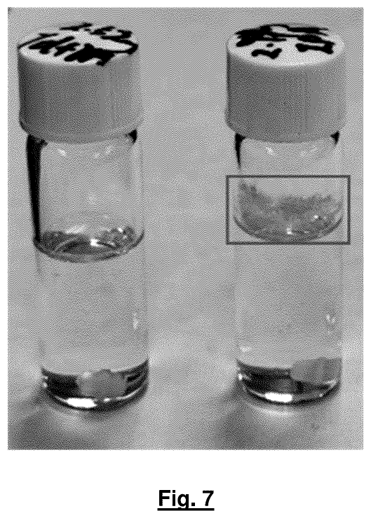

In addition, after being stored for 45 days in ambient, the size of aggregated SAM in neat IPA increased to over 100 nm (see FIG. 6), and some molecules can be seen to crystallize on the bottle wall (see FIG. 7), while the SAM in the mixed IPA:toluene solvent shows a much better shelf stability without forming aggregates. This indicates that such a solvent system is able to stabilize the SAM solute. Considering the differences in evaporation rate and surface tension (Tables 1 and 2 above) of the various solvent components in the mixed solution, which may affect the dispersion of Cbz-2Ph molecules during solution processing, an azeotrope ratio of 42 wt % toluene and 58 wt % IPA of the mixed solvent was therefore formulated for printing the Cbz-2Ph SAM. Different ratios and components of mixed solvents were also explored and the corresponding OSC devices were fabricated to demonstrate the effect (see Table 3.

TABLE 3
Device parameters with Cbz-2Ph SAM printed using different solvents.
(device area: 0.04 cm²) (“Tol”, “O-XY”, and “DMF”
are the abbreviation of toluene, O-xylene, and N,N-Dimethylformamide.)

| | V_{OC} | J_{SC} | FF | PCE |
|---|---|---|---|---|
| | (V) | (mA cm⁻²) | (%) | (%) |
| IPA:Tol = 1:1 | 0.853 | 27.84 | 76.24 | 18.11 |
| IPA:Tol = 1:5 | 0.825 | 29.54 | 73.85 | 18.00 |
| IPA:O-XY = 1:1 | 0.856 | 27.60 | 75.79 | 17.91 |
| IPA:DMF = 1:1 | 0.845 | 25.38 | 72.20 | 15.48 |

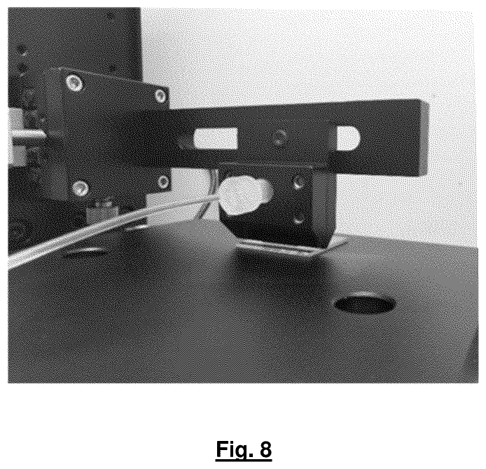

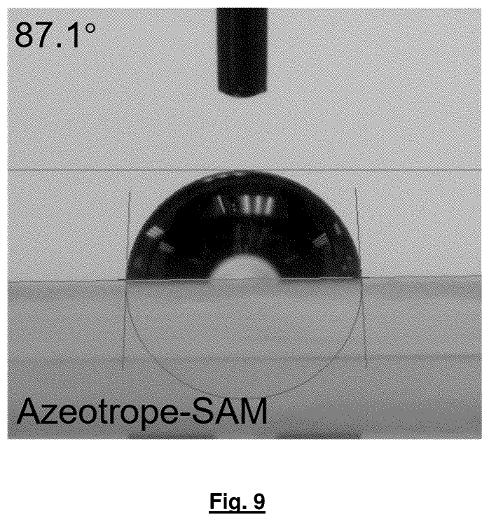

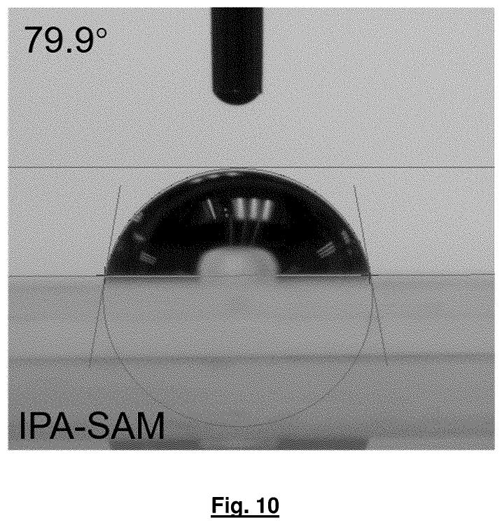

To evaluate how the azeotrope strategy of the present invention influences SAM formation, a slot-die coating platform (see FIG. 8) was used for printing the Cbz-2Ph SAM onto ITO substrates. Contact angle measurements, performed by dropping water on the Cbz-2Ph SAM films, were used to assess film quality. Ideally, all phosphonate groups should anchor to the ITO surface, with the carbazole head groups exposed outward to create a compact, hydrophobic surface. As shown in FIGS. 9 and 10, the azeotrope-SAM exhibited a larger contact angle compared to IPA-SAM, indicating denser and more uniform coverage of the SAM.

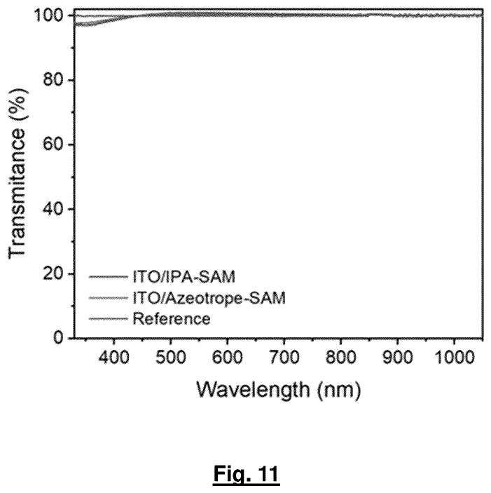

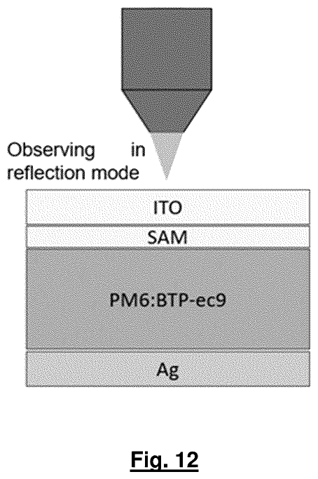

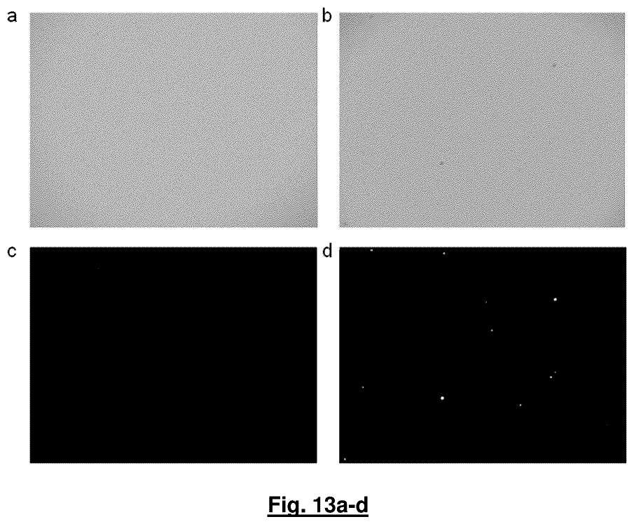

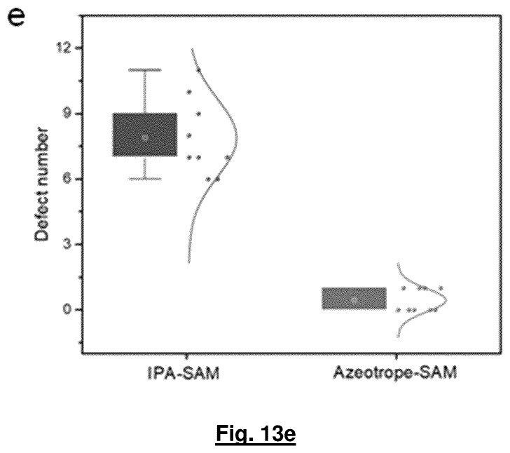

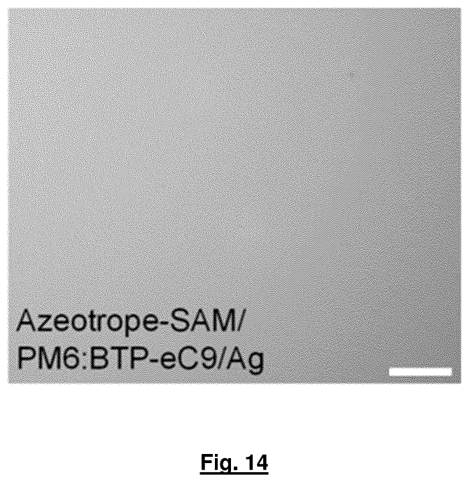

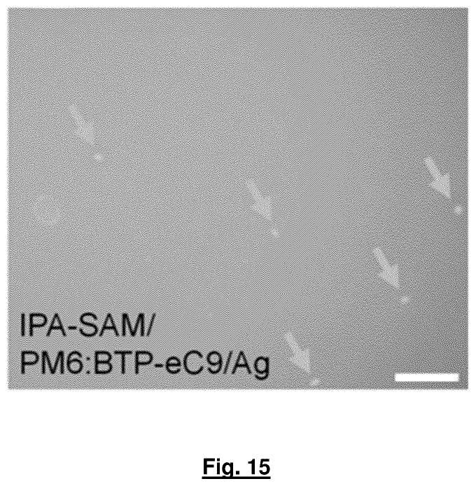

Further investigations focused on the impact of the azeotrope strategy on the morphology of the active layer. A PM6:BTP-eC9 BHJ layer with a thickness of 100 nm was deposited on the Cbz-2Ph-modified ITO substrates, followed by the thermal evaporation of a 100 nm Ag film. The high reflectance of the silver film and the high transmission in the visible light range of the Cbz-2Ph SAM (see FIG. 11) allowed observation of pinholes in the PM6:BTP-eC9 layer as bright dots under an optical microscope when viewed from the SAM side (schematic illustration in FIG. 12, with the statistical counts of defects being presented in FIG. 13). The azeotrope-SAM facilitated the formation of a more uniform PM6:BTP-eC9 layer compared to the IPA-SAM, with no observable pinholes (FIGS. 14 and 15). This highlights the importance of well-dispersed and stable SAM ink in determining the quality of the BHJ layer, consequently, forming a pin-hole-free active layer is critical to ensure high efficiency, stability, and reproducibility of OSCs.

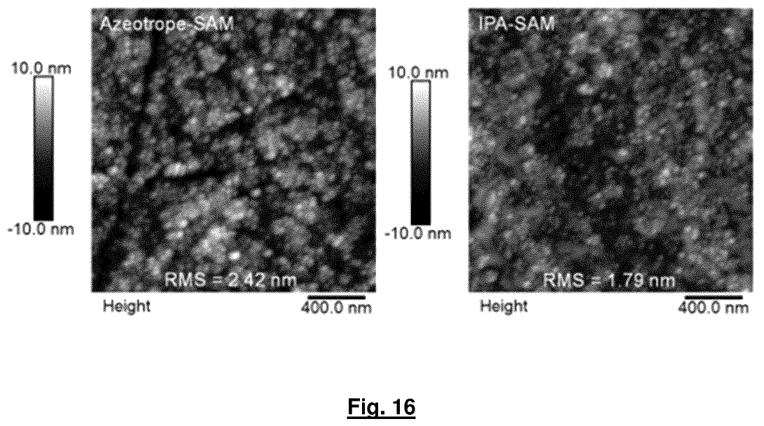

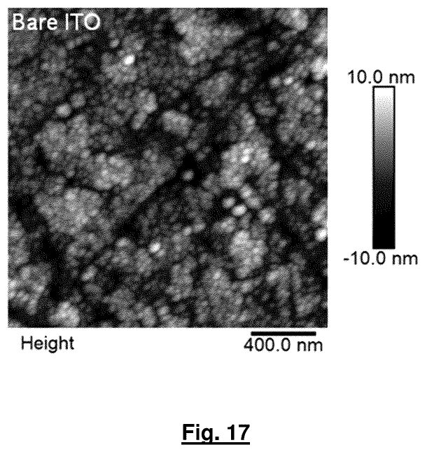

To further investigate how the azeotrope strategy enhances the quality of the processed SAMs, a suite of characterization techniques including atomic force microscope (AFM), Kelvin probe force microscopy (KPFM), ultraviolet photoelectron spectroscopy (UPS), and X-ray photoelectron spectroscopy (XPS) were utilized. As shown in FIG. 16, the AFM height images reveal a rougher surface with root-mean-square (RMS) roughness of 2.42 nm for the azeotrope-SAM sample, with morphology and RMS roughness closely matched with the bare ITO sample (see FIG. 17, RMS roughness=2.69 nm), suggesting a conformal coating of monolayer was formed. The IPA-SAM sample shows a smoother surface with RMS roughness of 1.79 nm, likely due to a multilayer film formation from the pre-aggregated Cbz-2Ph molecules during the printing process.

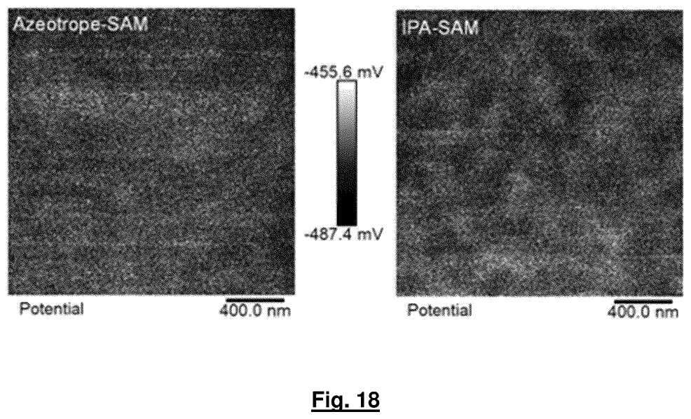

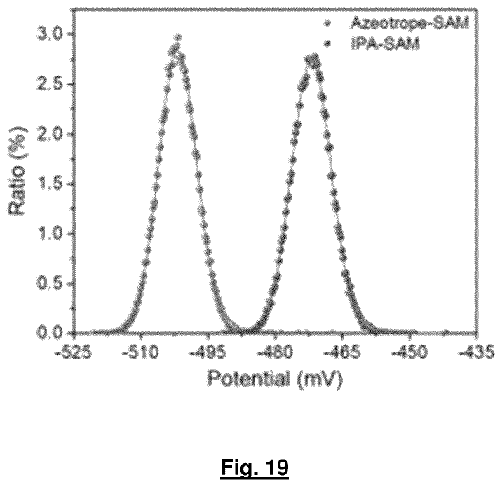

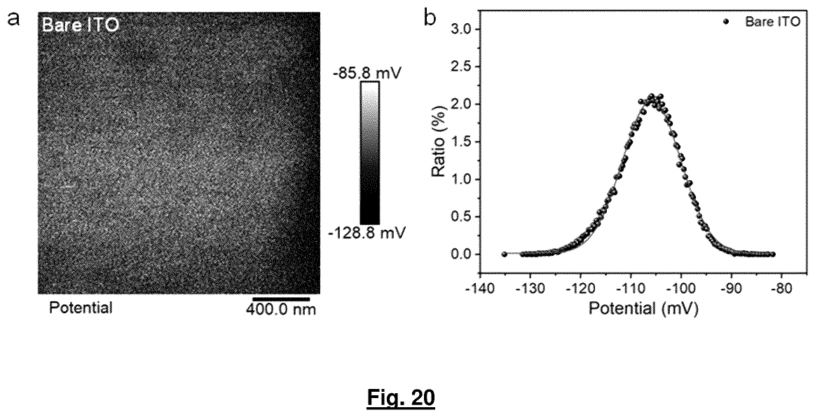

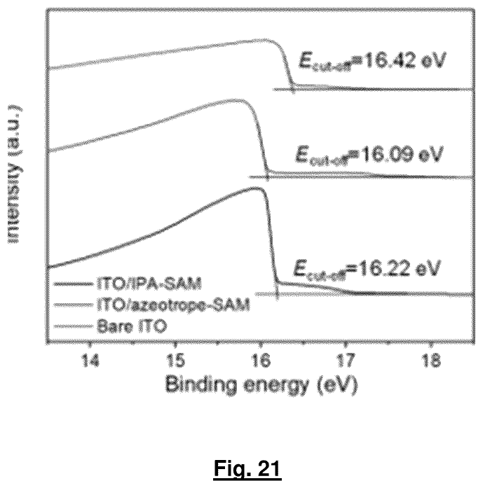

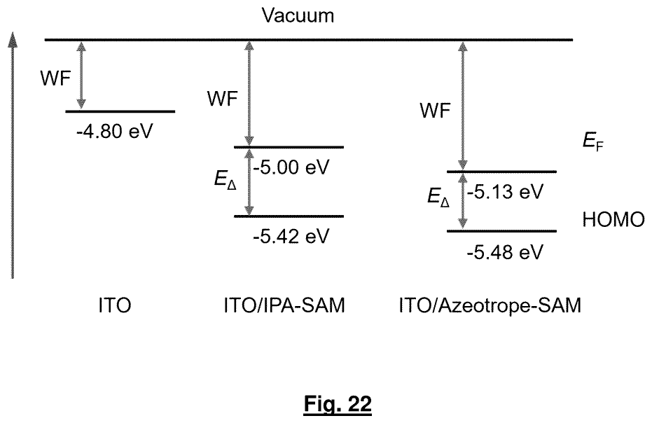

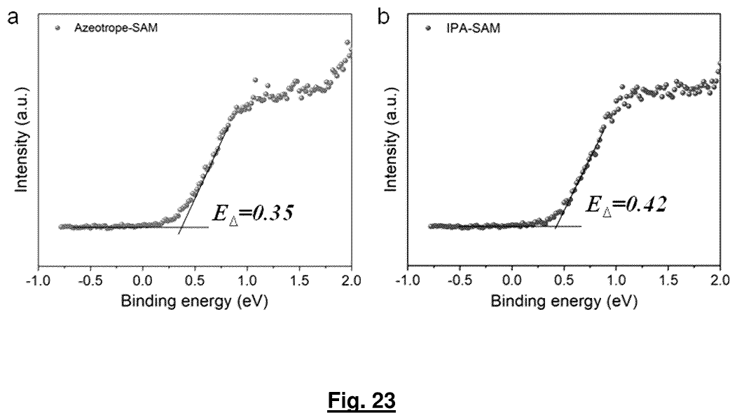

The uniformity of the SAMs can be better revealed by the surface potential distributions, captured by KPFM (see FIG. 18). The results distinctly show that a more uniform distribution of the surface potential is observed in the azeotrope-SAM sample, while the IPA-SAM shows a relatively inhomogeneous surface potential distribution, suggesting a more random alignment of the Cbz-2Ph molecules in the film. The statistical data of the surface potential values are shown in FIG. 19. Relative to bare ITO (see FIG. 20), the azeotrope-SAM demonstrates a larger energetic shift, suggesting a more effective modification of the ITO work function. This is supported by the UPS measurements for different samples (see FIGS. 21, 22 and 23), where the ITO/azeotrope-SAM exhibits a deeper-lying work function of −5.13 eV and a well-matched highest occupied molecular orbital (HOMO, −5.48 eV) with the ionization potential of PM6, potentially enhancing the open-circuit voltage (V_{OC}) of OSCs.

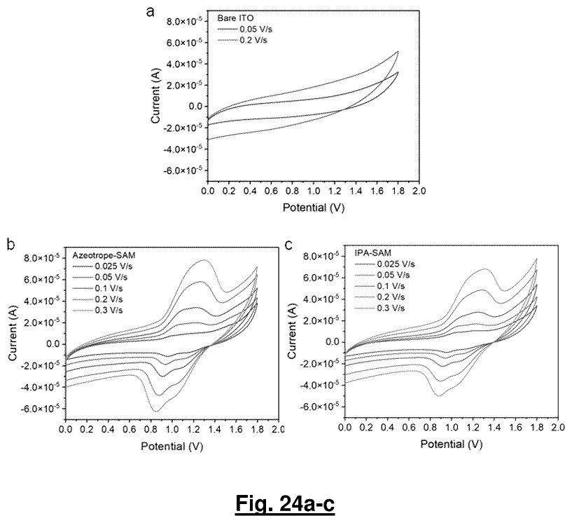

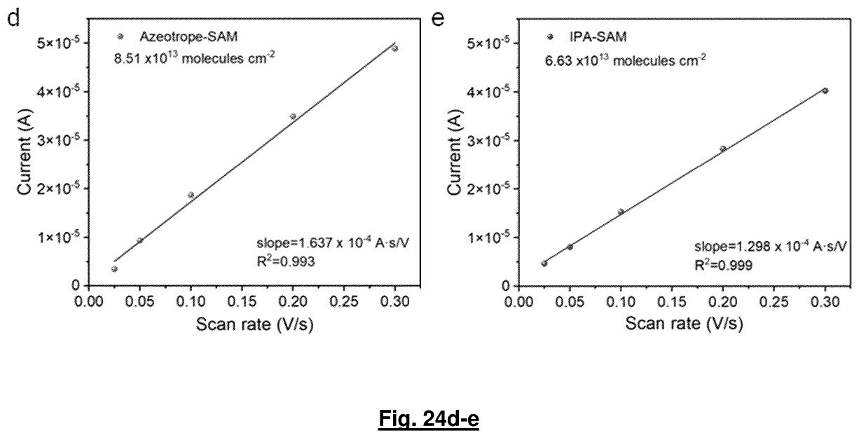

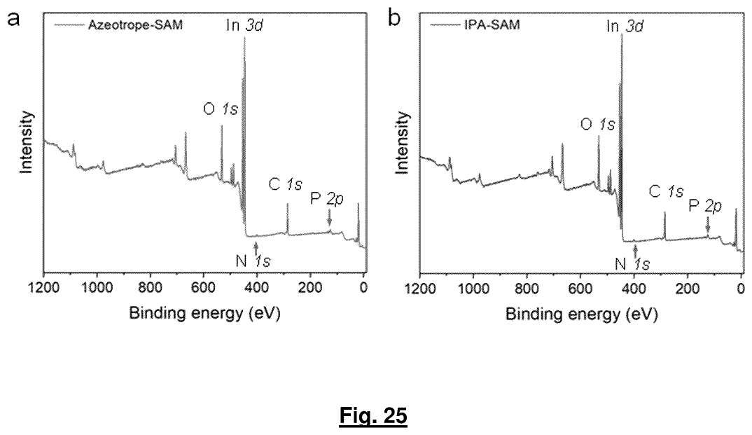

The surface density of Cbz-2Ph on ITO was further quantified using cyclic voltammetry (see FIG. 24), revealing a molecular density of 8.51×10¹³ molecules per cm² for the azeotrope-SAM, which is denser than that from the IPA-SAM (6.63×10¹³ molecules per cm²). Additionally, the XPS results also show a higher P/In elemental ratio for the azeotrope-SAM (see FIG. 25 and Table 4), indicating more effective anchoring of Cbz-2Ph molecules on the ITO surface when printed with suitable solvents. These results qualitatively and quantitatively show that the azeotrope strategy can facilitate the formation of a more compact SAM on ITO for further OSC fabrication.

TABLE 4
Atomic concentration determined by
XPS for azeotrope-SAM and IPA-SAM.

| | C | O | N | P | In | P/In |
|---|---|---|---|---|---|---|
| Azeotrope-SAM | 46.93 | 33.02 | 2.25 | 2.39 | 15.4 | 0.16 |
| IPA-SAM | 43.02 | 35.66 | 2.24 | 2.08 | 17 | 0.12 |

Following the characterization studies, SAM-based OSCs were fabricated with a conventional device architecture of ITO/Cbz-2Ph/PM6:BTP-eC9/PNDIT-F3N/Ag, having an effective area of 0.04 cm². To isolate the impact of the quality of printed SAM on OSC device performance, all devices were fabricated with a printed Cbz-2Ph SAM HSL, initially pairing with a spin-coated PM6:BTP-eC9 active layer and a PNDIT-F3N ESL, which are supposed to possess a lower defect density. Devices based on a spin-coated PEDOT:PSS HSL were also fabricated for comparison (see Table 5).

TABLE 5
Parameters for PEDOT:PSS-based devices (0.04 cm²). (Notes:
Statistics were calculated from 10 independent devices.)

| | | J_{SC} | | | J_{Cal}_{_{—}}_{EQE} |
|---|---|---|---|---|---|
| | V_{OC} | (mA | FF | PCE | (mA |
| | (V) | cm⁻²) | (%) | (%) | cm⁻²) |
| PEDOT:PSS | 0.829 | 27.71 | 77.76 | 17.86 | 26.30 |
| | (0.829 ± | (27.68 ± | (77.42 ± | (17.76 ± | |
| | 0.001) | 0.08) | 0.39) | 0.07) | |

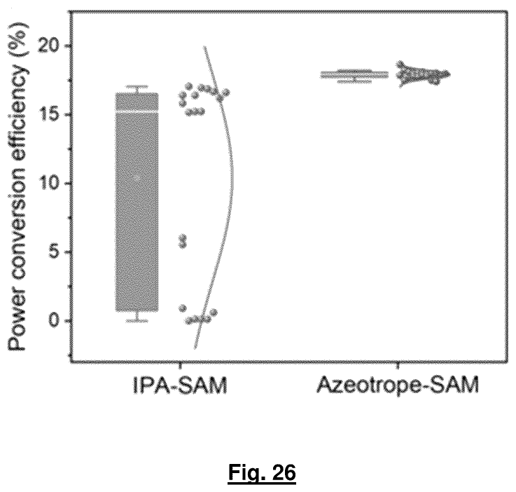

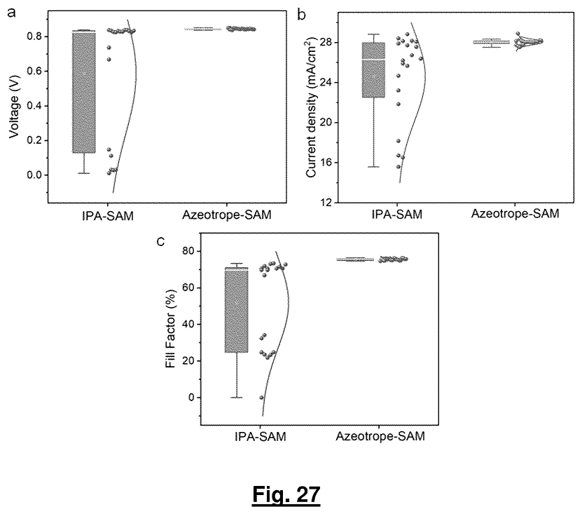

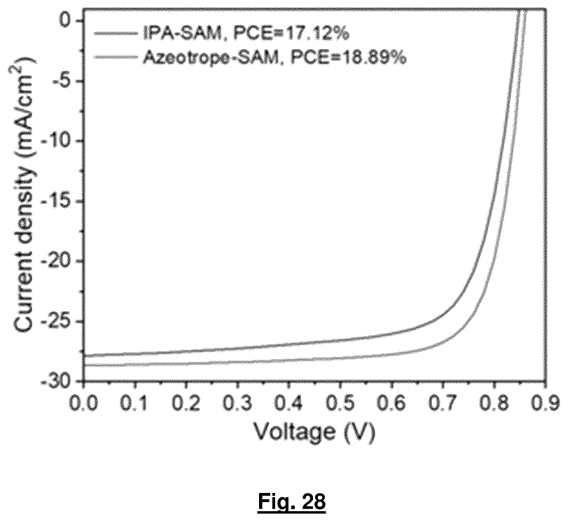

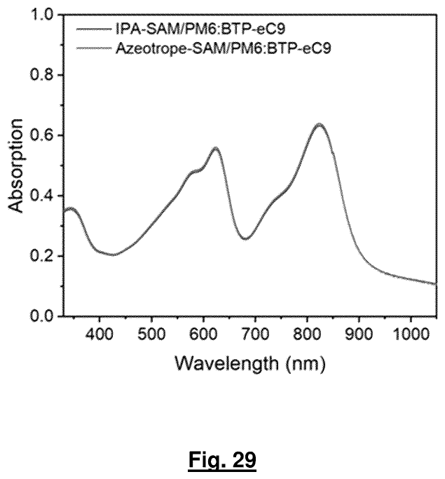

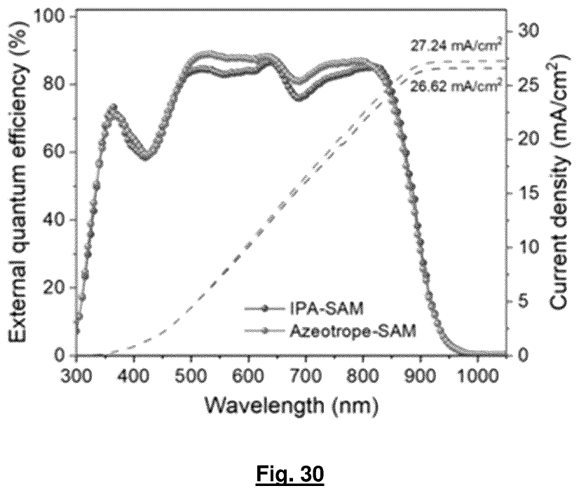

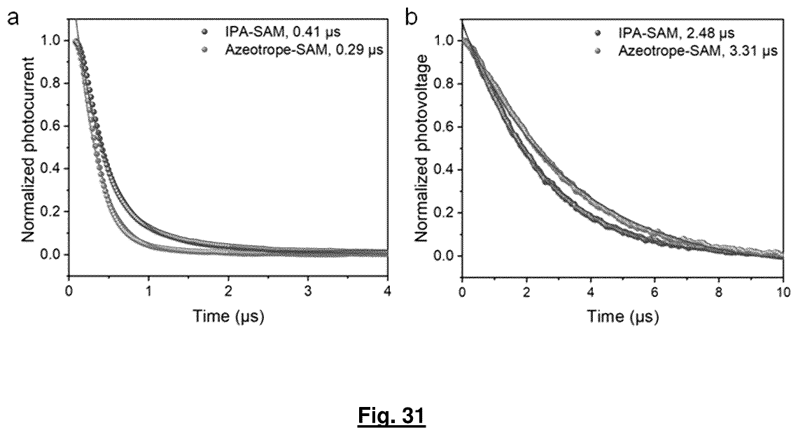

The statistics data of PCE based on azeotrope-SAM and IPA-SAM are plotted in FIG. 26, and the detailed parameters of V_{OC}, short-circuit current density (J_{SC}), and fill factor (FF) are shown in FIG. 27. The OSCs based on azeotrope-SAM show a very narrow PCE distribution, with the champion device delivered a high PCE of 18.89%. In contrast, the OSCs based on IPA-SAM show a broad PCE distribution, and the champion device showed a PCE of only 17.12%, which is even lower than the one obtained from PEDOT:PSS (PCE=17.86%) (see FIG. 28, Table 6 and the above Table 5). Notably, the azeotrope-SAM based devices outperform those of IPA-SAM in all key PV parameters: J_{SC} (28.62 mA cm⁻² vs. 27.86 mA cm⁻²), V_{OC} (0.859 V vs. 0.846 V), and FF (76.83% vs. 72.64%). Considering a negligible difference in the active layer absorption (see FIG. 29) from the two different devices, the improved external quantum efficiency (EQE) in the 500-800 nm (see FIG. 30) for the azeotrope-SAM devices suggests that the improved current density is primarily due to more efficient charge carrier extraction by the ITO substrates modified with azeotrope-SAM. A shorter extraction time from transient photocurrent measurements and a longer recombination lifetime from transient photovoltage measurements further confirm that azeotrope-SAM facilitates faster charge extraction and transport with less carrier recombination in the OSC (see FIG. 31).

TABLE 6
Detailed photovoltaic parameters of small-area devices (0.04
cm²). (Notes: Statistics were calculated from 10 independent devices.)

| | | J_{SC} | | | J_{Cal}_{_{—}}_{EQE} |
|---|---|---|---|---|---|
| | V_{OC} | (mA | FF | PCE | (mA |
| | (V) | cm⁻²) | (%) | (%) | cm⁻²) |
| IPA-SAM | 0.846 | 27.86 | 72.64 | 17.12 | 26.62 |
| | (0.845 ± | (27.95 ± | (71.76 ± | (16.95 ± | |
| | 0.003) | 0.19) | 0.71) | 0.13) | |
| Azeotrope- | 0.859 | 28.62 | 76.83 | 18.89 | 27.24 |
| SAM | (0.853 ± | (28.31 ± | (76.96 ± | (18.60 ± | |
| | 0.003) | 0.25) | 0.18) | 0.20) | |
| Printed | 0.855 | 28.23 | 77.30 | 18.65 | 26.91 |
| HSL + BHJ | (0.852 ± | (28.19 ± | (76.63 ± | (18.41 ± | |
| | 0.003) | 0.14) | 0.41) | 0.14) | |
| Printed p- | 0.850 | 27.85 | 77.20 | 18.28 | 26.66 |
| i-n stack | (0.850 ± | (28.11 ± | (76.20 ± | (18.21 ± | |
| | 0.002) | 0.26) | 0.83) | 0.05) | |

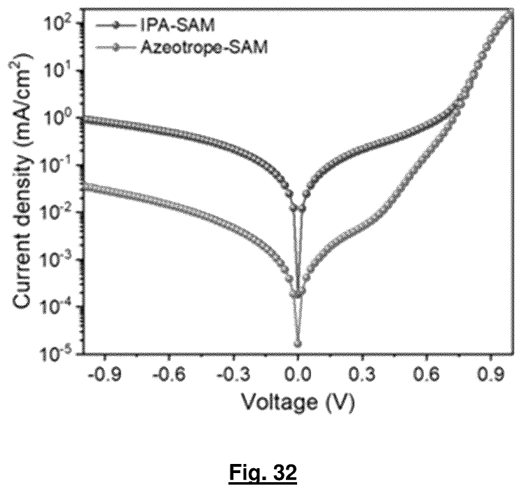

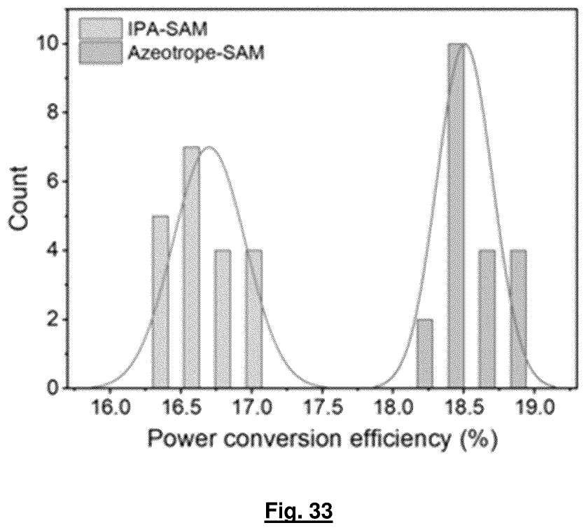

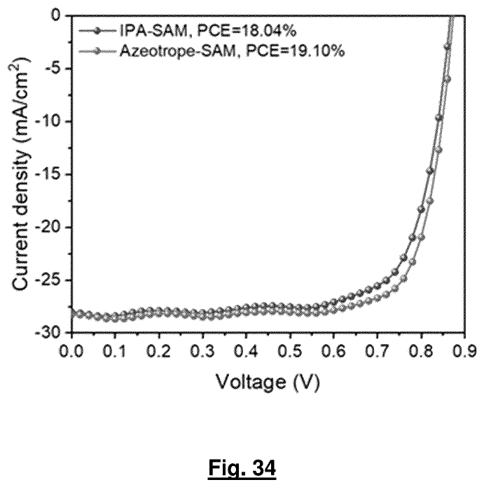

Dark current measurements were also performed on operational devices using both SAM types (see FIG. 32). Devices with azeotrope-SAM exhibited lower leakage currents, suggesting a denser Cbz-2Ph assembly and a pinhole-free morphology, which effectively mitigates potential short-circuit issues. Further analysis of the PCE distribution for the top 20 devices (out of 80 fabricated in 4 different batches) revealed that azeotrope-SAM devices display a more consistent and higher average PCE of 18.51±0.18%, compared to those with IPA-SAM at 16.70±0.25% (see FIG. 33). These results underscore the robustness of azeotrope-SAM for supporting additional functional layer processing and highlight its potential for scalable manufacturing of SAM-based OSCs. On the other hand, Poly[(2,6-(4,8-bis(5-(2-ethylhexyl)-4-fluoro)thiophen-2-yl)-benzo[1,2-b:4,5-b′]dithiophene)-alt-5,5′-(5,8-bis(4-(2-butyloctyl)thiophen-2-yl)dithieno[3′,2′:3,4;2″,3″:5,6]benzo[1,2-c][1,2,5]thiadiazole)](D18), another widely used donor material in high-efficiency OSCs, was tested. As shown in FIG. 34 and Table 7, the OSCs incorporating D18:BTP-eC9 on azeotrope-SAM exhibited a higher average PCE of 18.70%, compared to 17.83% on IPA-SAM. This highlights the broad applicability of the azeotrope strategy.

TABLE 7
Photovoltaics parameters of D18:BTP-
eC9-based organic solar cells.

| | V_{OC} | J_{SC}(mA | FF | PCE |
|---|---|---|---|---|
| | (V) | cm⁻²) | (%) | (%)^{a} |
| IPA-SAM | 0.866 | 28.02 | 74.28 | 18.04 |
| | (0.859 ± | (27.74 ± | (74.88 ± | (17.83 ± |
| | 0.007) | 0.56) | 1.15) | 0.29) |
| Azeotrope- | 0.873 | 28.29 | 77.30 | 19.10 |
| SAM | (0.869 ± | (28.24 ± | (76.22 ± | (18.70 ± |
| | 0.007) | 0.49) | 0.88) | 0.31) |

^{a}The parameters in brackets were averaged from 5 devices.

As discussed above, one of the most significant distinctions between OSC devices based on azeotrope-SAM and IPA-SAM lies in their reproducibility. For the 20 individual devices tested, a large portion of devices based on IPA-SAM showed abnormal PV performance, and some even showed no photovoltaic effect. Without intended to be limited by the theory, this adverse effect is attributed to the uneven coating of IPA-SAM on ITO, leading to direct exposure of ITO to the BHJ or pinholes formation in the BHJ films, as shown in FIG. 15. In stark contrast, azeotrope-SAM consistently yields much higher and more reproducible PCEs, which is particularly critical for the fabrication of printed OSCs with larger areas.

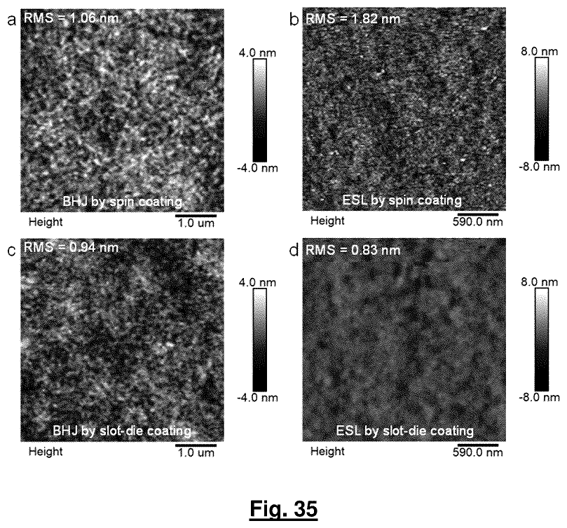

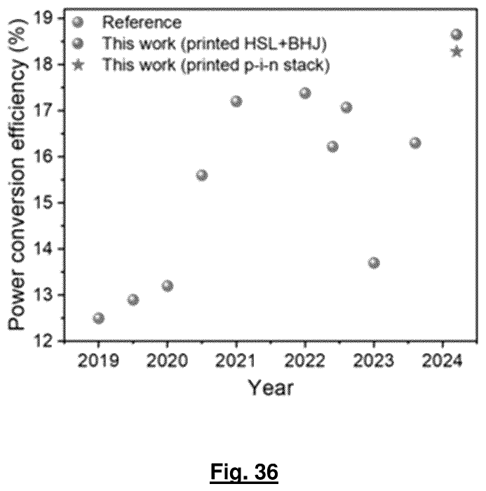

Given the recognized advantages of slot-die coating for scalable production, the performance of conventional OSC devices (area: 0.04 cm²) with a fully printed p-i-n functional layer stack was further explored. This approach is particularly meaningful for scalable OSC manufacturing as all functional layers (excluding the ITO and Ag electrodes) are printed via slot-die coating. AFM analysis of the surface morphology of ITO/azeotrope-SAM/BHJ and ITO/azeotrope-SAM/BHJ/ESL stacks showed comparable roughness to spin-coated BHJ layers and a smoother, more homogeneous morphology for the slot-die coated ESL (see FIG. 35). Table 6 and FIG. 36 present the photovoltaic performance of our all-printed OSCs, and also highlight the evolution in PCE of small-area (s 0.1 cm²) OSCs processed using slot-die coating (at least with the active layer processed from slot-die coating) over the past five years. Remarkably, all previous studies utilized non-SAM bottom contacts. A PCE of 18.65% was achieved with printed azeotrope-SAM and BHJ layers, and 18.28% with a fully printed p-i-n stack. To the best of our knowledge, these values currently set the benchmark in the field of printed OSCs.

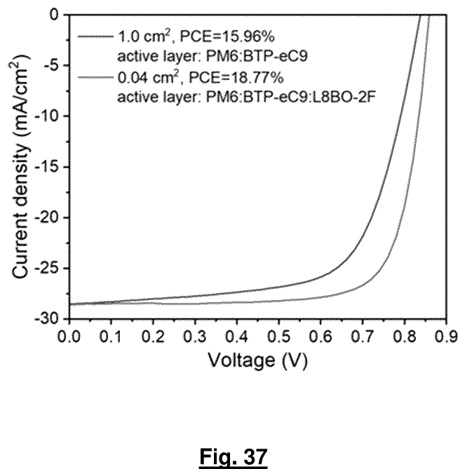

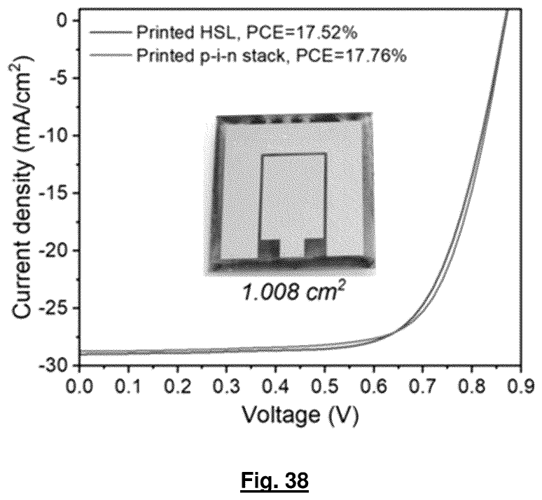

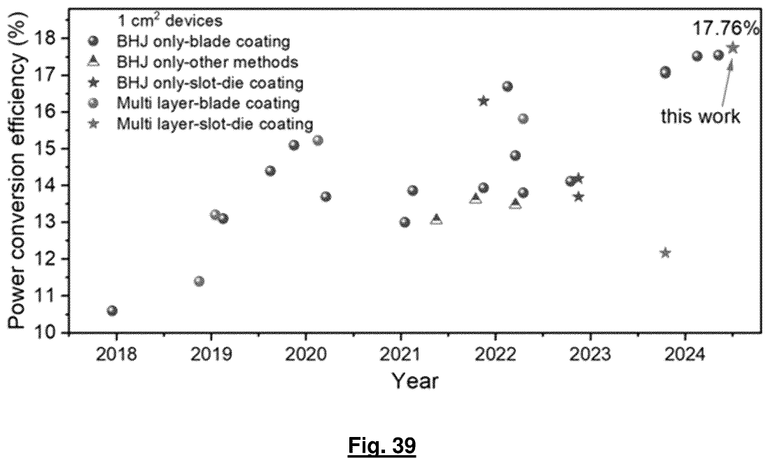

To validate the suitability for area scaling of our approach, devices with a larger active area of 1.008 cm² (1.12 cm×0.90 cm) were fabricated. This size is commonly chosen for large-area device demonstration prior to module fabrication. Similar to the small-area counterparts, devices with slot-die-coated HSL and fully slot-die-coated p-i-n stack were fabricated. For large-area devices, an improved BHJ with the inclusion of a ternary component, 2,2′-((2Z,2′Z)-((12,13-bis(2-ethylhexyl)-3,9-(2-butyloctyl)-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (L8BO-2F), was adopted to further improve the BHJ morphology, while the same device architecture of ITO/Cbz-2Ph/PM6:BTP-eC9:L8BO-2F/PNDIT-F3N/Ag was adopted (“PNDIT-F3N” being Poly[[2,7-bis(2-ethylhexyl)-1,2,3,6,7,8-hexahydro-1,3,6,8-tetraoxobenzo[lmn][3,8]phenanthroline-4,9-diyl]-2,5-thiophenediyl[9,9-bis[3′((N,N-dimethyl)-N-ethylamino) propyl]-9H-fluorene-2,7-diyl]-2,5-thiophenediyl]). It was found that such ternary blend devices can maintain a high FF in the scale-up process when compared to the binary blend devices (see Table 8, and FIG. 37). The resultant devices with a fully printed p-i-n stack present high PCEs of 18.77% for the 0.04 cm² devices (see Table 8 and FIG. 37), and 17.76% for the 1.008 cm² devices, which is even better than those based on printed HSL and spin-coated BHJ and ESL, which showed a PCE of 17.52% (see FIG. 38 and Table 9). This suggests that slot-die coating could provide better film uniformity than spin coating on large substrates, as the latter approach is known to suffer from intensive centrifugal force across the substrate, producing films with uneven thickness on large substrates. The good FF of 71.18% and a relatively modest area scale-up PCE loss of only 5.4% for the devices with a printed p-i-n stack demonstrates the viability of the azeotrope strategy for scalable OSC manufacturing. Surprisingly, although the slot-die coating is the most compatible method for OSC production, it was found during literature search that there are very limited reports on OSC with a fully slot-die coated p-i-n stack. Therefore, the performance of reported 1-cm² OSCs with at least one layer (usually the BHJ) being produced with scalable coating methods is summarized in FIG. 39, aiding the comparison of the advancement of our results with other reports.

TABLE 8
Parameters for 1.0-cm² device (with a structure of ITO/azeotrope-
SAM/PM6:BTP-eC9(slot-die coated)/PNDIT-F3N(slot-die coated) and
0.04-cm² device (with a structure of ITO/azeotrope-SAM/PM6:BTP-
eC9:L8BO-2F(spin-coated)/PNDIT-F3N(spin coated)/Ag)

| | | | J_{SC} | | |
|---|---|---|---|---|---|
| Device | Active | V_{OC} | (mA | FF | PCE |
| area | layer | (V) | cm⁻²) | (%) | (%) |
| 1.0 cm² | PM6:BTP-eC9 | 0.837 | 28.53 | 66.82 | 15.96 |
| 0.04 cm² | PM6:BTP-eC9:L8BO-2F | 0.858 | 28.57 | 76.54 | 18.77 |

TABLE 9
Detailed photovoltaic parameters of large-area devices (1 cm²)

| | | J_{SC} | | |
|---|---|---|---|---|
| | V_{OC} | (mA | FF | PCE |
| | (V) | cm⁻²) | (%) | (%) |
| Printed HSL | 0.867 | 28.99 | 69.75 | 17.52 |
| Printed p-i-n stack | 0.869 | 28.71 | 71.18 | 17.76 |

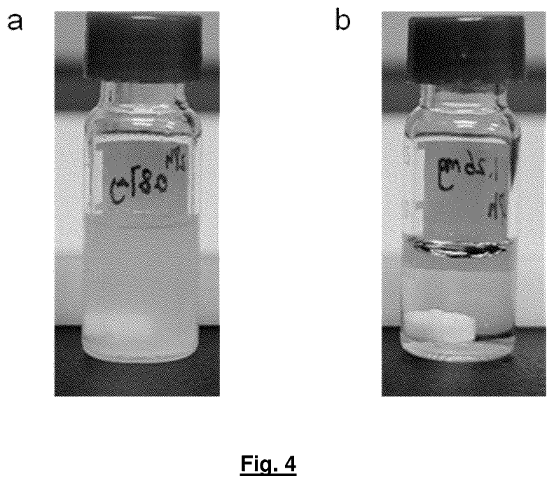

Finally, the operational stability of the OSCs was investigated by monitoring device performance at the maximum power point (MPP) under 1-sun equivalent LED illumination, with a temperature range of 45-50° C., as depicted in FIG. 4c. Devices based on azeotrope-SAM exhibited superior stability, achieving a T₈₀ lifetime exceeding 2,000 hours. In contrast, devices based on PEDOT:PSS displayed a much shorter T₈₀ lifetime of 169 hours. This reduction in lifespan is attributed to substantial burn-in loss observed during the initial stage of the stability test, a phenomenon frequently associated with poor interfacial stability at the BHJ and PEDOT:PSS interface.

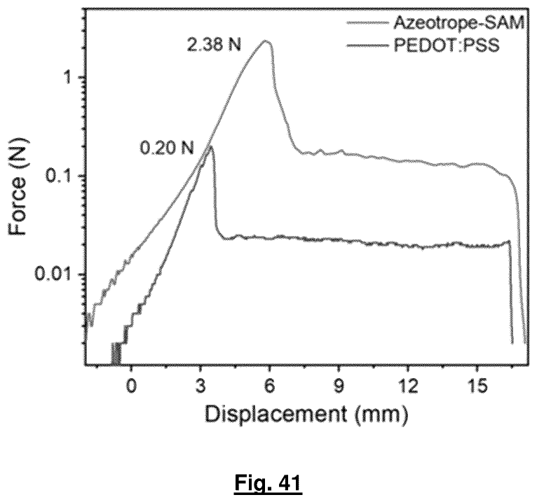

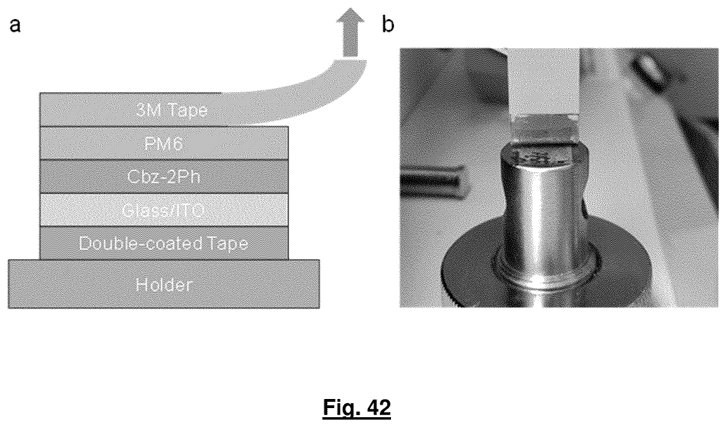

To explore potential reasons for the improved stability of azeotrope-SAM based devices, peel-off tests were conducted to evaluate the adhesion properties at the HSL/PM6 interface. The methodology involved attaching an adhesive tape to the PM6 film on the substrate (15 mm×15 mm). A force was then applied to the tape, peeling the PM6 film from the substrate and generating a force-displacement curve. The results of these tests are presented in FIGS. 41 and 42.

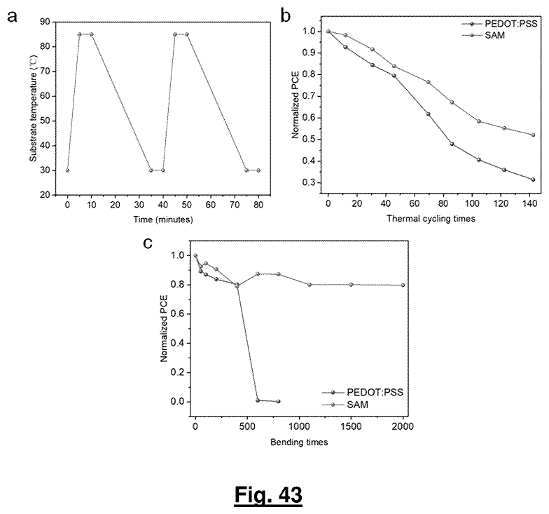

The force-displacement curve obtained from the peel-off test serves as a quantitative measure of the adhesion strength between the PM6 film and the underlying substrate. By analyzing the maximum force per unit area and the total energy required (calculated as the product of displacement and force) to detach the PM6 film, the adhesion strength can be accurately assessed. Notably, it required an order of magnitude more force or energy to peel the PM6 film from the ITO/azeotrope-SAM substrate compared to the ITO/PEDOT:PSS substrate, as detailed in Table 10. The enhanced adhesion at the HSL/BHJ interface potentially mitigates interface evolution under conditions of high temperature and mechanical stress, as demonstrated by the results of the thermal cycling and bending tests shown in FIG. 43. These tests indicate robust performance endurance under harsh conditions. This supports that the stronger adhesion plays a role in enhancing the stability of the device under long-term illumination, ensuring robust electrical contact, and prolonging the operational lifetime of the OSCs.

TABLE 10
Maximum force and total energy information
from the peel-off measurements

| | Maximum force | Total energy |
|---|---|---|
| | per unit area (N m⁻²) | per unit area (J m⁻²) |
| PEDOT:PSS | 897.78 | 2.06 |
| Azeotrope-SAM | 10617.78 | 25.09 |

### Materials

All the reagents were used as received without any further purification. PM6 and BTP-eC9 were purchased from Solarmer. Isopropanol (IPA), toluene, and chlorobenzene (CB) were purchased from Sigma-Aldrich. PNDIT-F3N was purchased from eFlexPV Limited.

### Synthesis of SAM

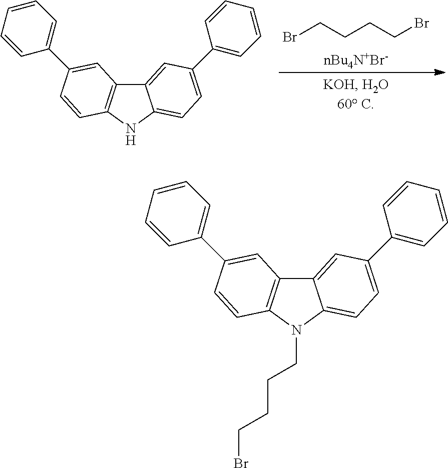

9-(4-bromobutyl)-3,6-diphenyl-9H-carbazole: 3,6-diphenyl-9H-carbazole (1.5 g, 4.7 mmol) was dissolved in 1,4-dibromobutane (20 eq, 20.28 g, 11.2 mL, 94 mmol), tetrabuthylammonium bromide (0.15 eq, 227 mg, 0.7 mmol) and 50% KOH aqueous solution (5 eq) were added subsequently. The reaction was stirred at 60° C. overnight. After completion of the reaction, extraction was done with dichloromethane. The organic layer was dried over anhydrous Na₂SO₄ and the solvent was distilled off under reduced pressure. The crude product was purified by column chromatography (Hex:DCM 4:1, v:v) to give 2.08 g (97.6%) of a colorless oil. ¹H NMR (300 MHz, Chloroform-d) δ 8.37 (d, J=1.7 Hz, 2H), 7.74 (ddd, J=8.1, 2.9, 1.5 Hz, 6H), 7.49 (t, J=7.7 Hz, 6H), 7.39-7.31 (m, 2H), 4.41 (t, J=6.8 Hz, 2H), 3.42 (t, J=6.4 Hz, 2H), 2.12 (dt, J=11.0, 6.5 Hz, 2H), 2.03-1.87 (m, 2H). ¹³C NMR (100 MHz, Chloroform-d) δ 142.0, 140.3, 132.7, 128.8, 127.3, 126.5, 125.5, 123.6, 119.1, 109.0, 42.5, 33.2, 30.2, 27.8.

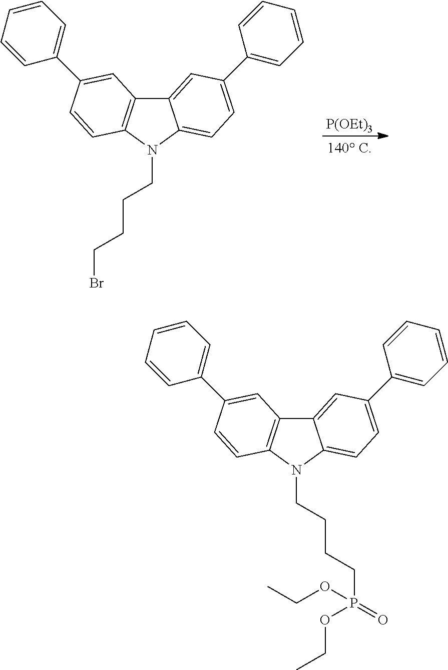 [SMILES: BrCCCCn1c2ccc(-c3ccccc3)cc2c2cc(-c3ccccc3)ccc21 ; CCOP(=O)(CCCCn1c2ccc(-c3ccccc3)cc2c2cc(-c3ccccc3)ccc21)OCC ; "P(OEt)3"]

Diethyl (4-(3,6-diphenyl-9H-carbazol-9-yl)butyl)phosphonate: 9-(4-bromobutyl)-3,6-diphenyl-9H-carbazole (2 g, 4.4 mmol) was dissolved in triethyl phosphite (20 eq, 14.6 g, 15 mL, 88 mmol) and the reaction mixture was heated at 145° C. overnight. After reaction completion, the solvent was distilled off under reduced pressure. The crude product was purified by column chromatography (DCM:EA 2:1, v:v) to give 2.1 g (93%) of colorless oil. ¹H NMR (400 MHz, Chloroform-d) δ 8.37 (d, J=1.8 Hz, 2H), 7.74 (dt, J=8.1, 1.3 Hz, 6H), 7.53-7.45 (m, 6H), 7.39-7.33 (m, 2H), 4.37 (t, J=7.0 Hz, 2H), 4.09-3.99 (m, 4H), 2.08-2.00 (m, 2H), 1.81-1.65 (m, 4H), 1.26 (t, J=7.1 Hz, 6H). ¹³C NMR (100 MHz, Chloroform-d) δ 142.0, 140.3, 132.6, 128.8, 127.3, 126.5, 125.5, 123.6, 119.0, 109.0, 61.6, 61.6, 42.8, 29.9, 29.8, 26.2, 24.8, 20.5, 20.5, 16.5, 16.4.

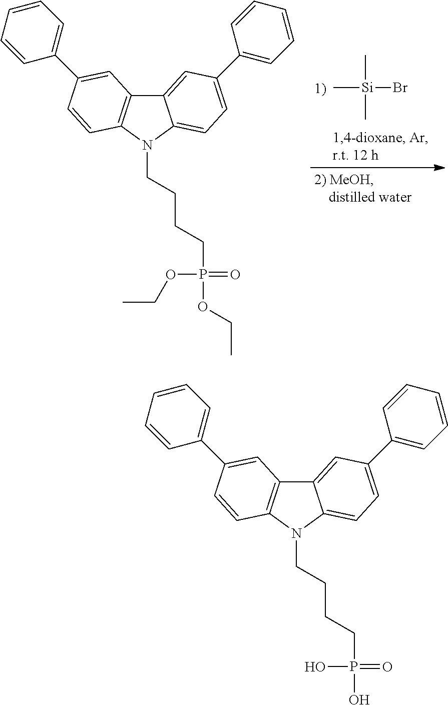

(4-(3,6-diphenyl-9H-carbazol-9-yl)butyl)phosphonic acid (JJ36): Diethyl (4-(3,6-diphenyl-9H-carbazol-9-yl)butyl)phosphonate (1 g, 1.95 mmol) was dissolved in anhydrous 1,4-dioxane (30 mL) under argon atmosphere and bromotrimethylsilane (10 eq, 3.0 g, 2.6 mL, 19.55 mmol) was added dropwise. The reaction was stirred for 12 h at room temperature under an argon atmosphere. Afterwards solvent was partially distilled off under reduced pressure, and the liquid residue was dissolved in methanol (10 ml). Next, distilled water was added dropwise (30 ml), until the solution became opaque. Product was filtered off and washed with water to give 0.75 g (84%) of a white solid. ¹H NMR (400 MHz, DMSO-d₆) δ 8.64 (d, J=1.8 Hz, 2H), 7.80 (t, J=9.5 Hz, 6H), 7.70 (d, J=8.5 Hz, 2H), 7.49 (t, J=7.6 Hz, 4H), 7.34 (t, J=7.4 Hz, 2H), 4.44 (m, overlapped 14H), 1.89 (t, J=7.3 Hz, 2H), 1.58 (h, J=8.1, 7.4 Hz, 4H). ¹³C NMR (100 MHz, DMSO-d₆) δ 141.52, 140.51, 131.67, 129.36, 127.13, 126.95, 125.33, 123.43, 119.24, 110.36, 42.75, 30.23, 30.07, 28.51, 27.15, 20.94, 20.90.

### Device Fabrication

The ITO substrates were cleaned by ultrasonication sequentially with dilute detergent solution, deionized water, acetone, and isopropanol for 20 min each step before being dried in an oven setting @80° C. The substrates were treated with UV-ozone for 20 min before use. PEDOT:PSS was spin-coated on the ITO substrates (15 mm×15 mm for 0.04-cm² devices and 25 mm×25 mm for 1-cm² devices) and annealed at 150° C. for 10 min in air. The SAM solutions were prepared by dissolving SAM powder in IPA, toluene, or azeotrope of IPA and toluene (with a weight ratio of 0.58:0.42) at 1 mg/ml concentration and stirred for 2 hours before use. All layers printed by slot-die coating platform were performed in ambient conditions with a controlled relative humidity (around 15%). The printing velocity, gap between coating head and substrate, flow rate, and substrate temperature for SAM were adjusted to 25 mm/s, 100 μm, 5 μL/min, and 80° C. After annealing at 100° C. for 10 min, the substrate was transferred into the glove box for temporary storage. PM6:BTP-eC9 (1:1.2) or PM6:BTP-eC9:L8BO-2F (1:0.96:0.24) blend was dissolved in chlorobenzene with a concentration of 10 mg/ml for slot-die coating and 22 mg/ml for spin coating (without any additive). The solution was stirred at 50° C. for at least 1 h. The printing velocity, printing gap, flow rate, and substrate temperature for slot-die coated active layer were adjusted to 50 mm/s, 150 μm, 10 μL/min, and 70° C. For the spin-coated active layer, the rotation speed is 2500 rpm. After coating, the active layer was annealed at 100° C. for 5 min. PNDIT-F3N was dissolved in methanol (with 0.5 vt % acetic acid) with 0.5 mg/ml concentration for spin coating and 3 mg/ml for slot-die coating. The printing velocity, printing gap, flow rate, and substrate temperature for slot-die coated PNDIT-F3N were adjusted to 5 mm/s, 100 μm, 5 μL/min, and room temperature. For devices adopting D18/BTP-eC9 as the active layer, D18 film was spin-coated on the SAM or PEDOT:PSS layer from the chlorobenzene with a rotation velocity of 2600 rpm, then BTP-ec9 dissolved in chloroform was spin-coated on the D18 layer with a rotation velocity of 2000 rpm. The concentrations of D18 and BTP-eC9 in solvents are 6 mg/ml and 10 mg/ml, respectively. The heating temperature of D18 solution and BTP-eC9 solution are 80° C. and 45° C., respectively. For spin-coated PNDIT-F3N, the rotation speed is 2000 rpm. Then, samples were transferred to the evaporation chamber for the deposition of Ag (100 nm). The OSCs have an identical active area of 0.04 cm² defined by the overlap area of the anode and the cathode. For J-V performance measurement, a test mask with an accurate area of 0.0324 cm² was used. For 1-cm² devices, the width of the coating head of the slot-die coating platform was adjusted to 30 mm, while 12 mm for 0.04-cm² devices. A mask design with a width of 9 mm (this value is larger than the width of a sub-cell in common OPV or perovskite modules, which is usually at 5-7 mm due to the balancing between geometry fill factor and charge carrier transport) and a length of 11.2 mm was employed for 1-cm² devices to explore the feasibility of further scaling-up process.

### Instruments and Characterizations

Dynamic light scattering (DLS) experiments were conducted by a dynamic light scattering particle size Analyzer (Malven Zeta sizer Nano ZS) at 25° C. with a monochromatic coherent He—Ne laser (640 nm) as the light source. An avalanche photodiode detector that detected the scattered light at an angle of 173°. DLS measurements were carried out in SAM solutions in IPA, toluene, or other mixed solvents to determine the size of the particles. Contact angle was measured with a DataPhysics contact angle tester and the water drop volume was set as 3 μL. The cyclic voltammetry experiments were performed at room temperature in a nitrogen atmosphere with a three-electrode system using a bare ITO or SAM-modified ITO as the working electrode, Pt wire as the counter electrode, and an Ag/AgCl (saturated KCl) as the reference electrode. Tetrabutylammonium phosphorus hexafluoride (Bu₄NPF₆, 0.1M) in o-DCB solution was used as the supporting electrolyte, and a series of scan rates was applied. For calibration, the redox potential of ferrocene/ferrocenium (Fc/Fc+) was measured under the same condition. The detailed calculation for the surface density of SAM molecules on ITO can be found in literature.¹

AFM and KPFM images were probed by a Dimension Icon AFM (Bruker) with the tapping mode at ambient conditions. UV-vis absorption spectra were characterized by a Hitachi UH4150 UV-VIS-NIR Spectrophotometer.

The devices used for maximum power point (MPP) tracking were constructed using the same methods outlined in the “Device Fabrication” section. This involved using printed azeotrope-SAM and spin-coated PEDOT:PSS as the hole-selective layers (HSL), respectively, and printed PM6:BTP-eC9 for the active layer, with silver electrodes evaporated using the same mask. For the stability assessments, these devices were placed in an MPP tracking box situated within a nitrogen glove box, and they were tested without encapsulation. The LED light source was calibrated to provide one sun illumination during the MPP tracking, and the ambient temperature within the testing box was maintained at approximately 45-50° C., according to the temperature sensor readings.

The thermal cycling test was conducted in a nitrogen glove box with temperature variations ranging from 30° C. to 85° C. Device structure for the thermal cycling test is glass/ITO/SAM or PEDOT:PSS/PM6:BTP-eC9/PNDIT-F3N/Ag. The heating of the substrate and subsequent cooling at ambient temperatures facilitated this process.

For the mechanical bending tests on flexible devices (PET/ITO/SAM or PEDOT:PSS/PM6:BTP-eC9/PNDIT-F3N/Ag), these were performed under a constant bending radius of 6 mm, verified using an optical rod of the same diameter.

The UPS and XPS characterizations were performed by a VG ESCALAB 220i-XL surface analysis system equipped with a He discharge lamp (hv=21.22 eV) and a monochromatic Al-Kα X-ray gun (hv=1486.6 eV). The SAM solutions were deposited on ITO in the same process as device fabrication. Typically, the characterized peak of hydrocarbon C1s from adventitious carbon at 284.8 eV was used for binding energy calibration.

The J-V characteristics of the OSC devices were measured under a solar simulator (Enlitech, SS-F5, Taiwan) using a Keithley 2400 source meter in a nitrogen glove box at room temperature. The light intensity is calibrated using KG2 NREL-calibrated silicon solar cells, giving a value of 100 mW cm⁻². EQE spectra are measured by EnLi Technology (Taiwan) EQE measurement system equipped with a standard silicon diode, where the monochromatic light was generated from a Newport 300 W lamp.

In this study, an azeotrope strategy utilizing a mixed, azeotropic solvent of IPA and toluene was developed for large-area printing of Cbz-2Ph SAM. This approach effectively addresses the challenges associated with the amphiphilicity of SAM and the complex kinetics induced by non-uniform evaporation of mixed solvents. The Cbz-2Ph molecules in the azeotrope exhibit single-molecule scale dispersion and show no micelle formation even after 45 days of storage in ambient conditions. Compared to the IPA-SAM HSL, the azeotrope-SAM forms a more compact and homogeneous distribution on the rough ITO surface, which supports the formation of a high-quality active later atop, significantly minimizing pinhole formation.

Critically, azeotrope-SAM is more effective in modifying ITO work function, enabling a better energetic alignment between the HSL and the active layer. Consequently, OSCs based on azeotrope-SAM exhibit superior device performance compared to those using IPA-SAM, achieving an impressive PCE of 18.89% for small-area (0.04 cm²) devices. For large-area devices with a fully printed p-i-n stack, a PCE of 17.76% was achieved, setting the current record for 1-cm² OSCs. Additionally, the OSC devices based on azeotrope-SAM also exhibit better stability (T₈₀=2017 hours) than those based on conventional PEDOT:PSS (T₈₀=169 hours) under prolonged 1-sun illumination, as the SAM establishes a more robust interface between the ITO electrode and the active layer. With its substantial improvements in device performance and operational stability, the azeotrope strategy offers a promising avenue for further development and commercialization of OSC technologies.

In the above discussion, the SAM (Cbz-2Ph) has the following structure: namely, the anchoring group is PO₃H₂, the alkyl chain bridge is butyl, and the functional head group is carbazole derivatives with the substituents of benzene.

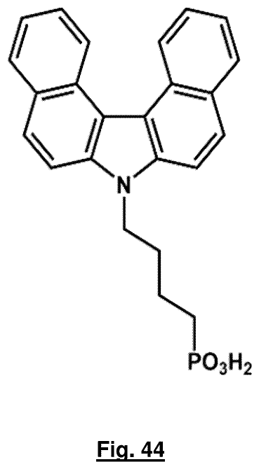

To show the effect of azeotrope-treated SAM in PSCs, perovskite solar cells with a structure of ITO/Cbz-NaPh/perovskite/EDADI/C₆₀/BCP/Ag (bandgap: 1.85 eV) (“EDADI” being ethylenediamine dihydroiodide, and “BCP” being bathocuproine) were fabricated based on azeotrope-treated SAM and IPA-treated SAM. The SAM molecule structure was selected, as FIG. 44 shows, and named as “Cbz-NaPh”, in which the anchoring group is PO₃H₂, the alkyl chain bridge is butyl, and the functional head group is carbazole derivatives with the substituents of napththalene.

The precursor perovskite solution was prepared by dissolving 0.8 mmol formamidinium iodide (FAI), 0.1 mmol caesium iodide (CsI), 0.1 mmol methylammonium iodide (MAI), 0.75 mmol PbI₂ and 0.75 mmol PbBr₂ in 1 mL of a mixed solvent consisting of dimethylformamide (DMF) and (dimethyl sulfoxide) DMSO with a volume ratio of 4:1. This was based on the stoichiometric formula of FA_{0.8}MA_{0.1}Cs_{0.1}Pb(I_{0.5}Br_{0.5})₃. The perovskite precursor solution was thoroughly dissolved and aged over 2 hours before use. Phenylethylammonium acetate (PEAAc) primary solution was prepared by dissolving 0.1 mmol solid PEAAc in 1 mL of DMF/DMSO. Then, 40 μL PEAAc primary solution was added to 1 mL control perovskite precursor to form the target perovskite precursor.

The solution of self-assembled molecules was prepared by dissolving in azeotrope of IPA and toluene or in pure IPA solvent with a concentration of 1 mg/ml. For preparing the perovskite passivation solution, 1 mg of EDADI was added to 1 mL of IPA. For the fabrication of perovskite cells, all processes were performed in a N₂-filled glove box. The IPA-treated Cbz-NaPh SAM was prepared by spin coating the SAM solution on pre-cleaned glass/ITO substrates at 3000 rpm for 30 s. The azeotrope-treated Cbz-NaPh SAM was prepared using blade coating. The blade coating velocity, gap between the doctor blade and substrate, and substrate temperature for Cbz-NaPh were adjusted to 15 mm/s, 120 μm, and 80° C. Both azeotrope-treated SAM and IPA-treated SAM were annealed at a hot plate with a setting temperature of 100° C. for 10 min after coating. When the sample cooled to room temperature, the SAM layer was washed using the IPA at 3000 rpm for 30 s, followed by 5 min annealing at 100° C.

Based on a two-step spin-coating process, the perovskite layers were prepared on top of the SAM layer at the first step at 1000 rpm for 10 s and the second step at 4000 rpm for 40s. In the spin-coating process, 180 μL CB as antisolvent was dripped at 25 s of the second step before the end of the spin-coating program. And then, the sample was quickly transferred to the hot stage to anneal within 10 min. The passivation layer was done by spin-coating EDADI at 5000 rpm followed by 10 min of annealing at 100° C. Then, the samples were transferred to thermal evaporation equipment to deposit the electron-transportation layers and electrode, where C60 (25 nm)/BCP (6 nm)/Ag (100 nm) were sequentially deposited.

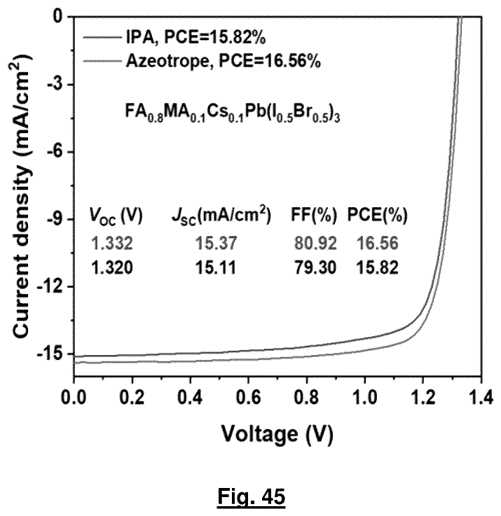

The performance of PSCs was evaluated using J-V curves, as shown in FIG. 45. The higher VOC (1.332 V vs. 1.320 V) in azeotrope-treated PSC proves a better Cbz-NaPh layer formed between ITO and perovskite, thus leading to a more suitable energy level. In addition, the higher FF (80.92% vs. 79.30%) indicates better perovskite morphology formed based on the azeotrope-treated Cbz-NaPh. A PCE of 16.56% for azeotrope-treated PSC (15.82% for IPA-treated PSC) can powerfully prove that this SAM treatment strategy can also improve the PSC performance and be adopted in the PSC field.

It should be understood that the above only illustrates and describes examples whereby the present invention may be carried out, and that modifications and/or alterations may be made thereto without departing from the spirit of the invention.

For example, the anchoring group of the SAM may include silane- and acid-based (sulfonic acid, phosphonic acid, acetic acid, boronic acid, catechol, silicic acid, and phenol) anchoring groups for oxide substrates and thiol-, dithiocarbamate, and N-heterocyclic carbenes-based) anchoring groups for metal substrates. The spacer group, may include alkyl chains and aromatic conjugated moieties. The functional head group may include polythiophene, carbazole derivatives, aromatic conjugated moieties, phenothiazine derivatives, alkyl chains derivatives, n-type semiconductors, e.g., modified fullerene and perylene diimide.

Similarly, the anchored substrates may be metals (such as gold (Au), silver (Ag), copper (Cu), platinum (Pt), mercury (Hg), etc.) and metal oxides (such as barium oxide (BaO), magnesium oxide (MgO), hafnium (IV) oxide (HfO₂), zinc oxide (ZnO), aluminium oxide (Al₂O₃), titanium dioxide (TiO₂), indium (III) oxide (In₂O₃), tin (IV) oxide (SnO₂), nickel oxide (NiOₓ), silicon dioxide (SiO₂), ITO, FTO, etc.).

In addition to toluene and isopropanol, the azeotropic components for the SAM may include other polar solvents, such as ethanol, methanol, and N,N-dimethylformamide, as well as aromatic solvents such as benzene, xylene, and dichlorobenzene. For other non-SAM solutes, the azeotrope components may be selected based on functional group.

The present invention may be practiced not only by slot-die coating, but also by a variety of film fabrication techniques, including spin coating, blade coating, screen printing, spray coating, and brush coating. This versatility allows the azeotropic method to be adapted to different manufacturing processes and scale requirements.

It should also be understood that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

1. A solution of self-assembled monolayer (SAM) molecules, including a plurality of SAM molecules dissolved in at least two solvents which form an azeotropic solvent system.

2. The solution of claim 1, wherein said SAM molecules include an anchoring group selected from a group consisting of silane-based anchoring group, acid-based anchoring group, thiol-based anchoring group, dithiocarbamate anchoring group, and N-heterocyclic carbenes-based anchoring group.

3. The solution of claim 2, wherein said acid based anchoring group includes sulfonic acid, phosphonic acid, acetic acid, boronic acid, catechol, silicic acid, and phenol.

4. The solution of claim 1, wherein said SAM molecules include a spacer group selected from a group consisting of alkyl chains and aromatic conjugated moieties.

5. The solution of claim 1, wherein said SAM molecules include a functional head group selected from a group consisting of polythiophene, carbazole derivatives, aromatic conjugated moieties, phenothiazine derivatives, alkyl chains derivatives, n-type semiconductors, modified fullerene and perylene diimide.

6. The solution of claim 1, wherein said SAM molecules include a compound of the following Formula (I) or Formula (II):

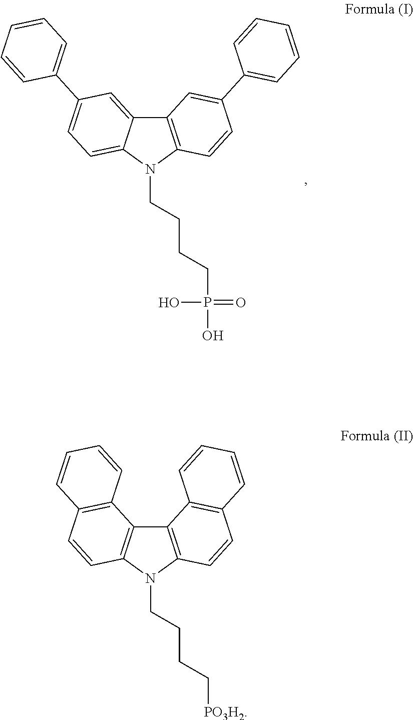

7. The solution of claim 1 wherein said azeotropic solvent system includes at least two different solvents each selected from a group consisting of polar solvents and aromatic solvents.

8. The solution of claim 7, wherein said polar solvents include isopropanol, ethanol, methanol, and N,N-dimethylformamide.

9. The solution of claim 7, wherein said aromatic solvents include toluene, benzene, xylene, and dichlorobenzene.

10. The solution of claim 1, wherein said azeotropic solvent system includes toluene and isopropanol.

11. The solution of claim 10, wherein said toluene is of substantially 42 wt % and said isopropanol is of substantially 58 wt %.

12. A method of forming a SAM film on a substrate, including:
applying a solution of SAM molecules according to claim 1 on a substrate by coating.

13. The method of claim 12, wherein said solution of SAM molecules is applied on said substrate by slot-die coating, spin coating, blade coating, screen printing, spray coating, and/or brush coating.

14. The method of claim 12, wherein said substrate is made of a metal or metal oxide.

15. The method of claim 14, wherein said substrate is made of gold (Au), silver (Ag), copper (Cu), platinum (Pt), mercury (Hg), barium oxide (BaO), magnesium oxide (MgO), hafnium (IV) oxide (HfO₂), zinc oxide (ZnO), aluminium oxide (Al₂O₃), titanium dioxide (TiO₂), indium (III) oxide (In₂O₃), tin (IV) oxide (SnO₂), nickel oxide (NiOₓ), silicon dioxide (SiO₂), indium tin oxide (ITO) or fluorine-doped tin oxide (FTO).

16. A solar cell including a substrate with a SAM film formed according to the method of claim 12.

17. The solar cell according to claim 16, wherein said solar cell comprises an organic solar cell (OSC) or a perovskite solar cell (PSC).

18. Use of an azeotropic solvent mixture including at least two solvents in solution-processing film fabrication to maintain consistent solvent composition during film fabrication.
